(19) United States
(12) Patent Application Publication
(10) Pub. No.: US 2017/0256741 A1
(43) Pub. Date: Sep. 7, 2017

(54) BARRIER FILM AND ELECTRICAL DEVICE INCLUDING THE SAME

(71) Applicant: SAMSUNG ELECTRONICS CO., LTD., Suwon-si (KR)

(72) Inventors: Yoon Chul SON, Hwaseong-si (KR); In Taek HAN, Seoul (KR); Doh Won JUNG, Seoul (KR)

(21) Appl. No.: 15/268,473

(22) Filed: Sep. 16, 2016

(30) Foreign Application Priority Data
Mar. 4, 2016 (KR) 10-2016-0026646

(51) Int. Cl. H01L 51/52; B32B 37/14

(52) U.S. Cl. CPC H01L 51/5256; B32B 37/14; B32B 2457/00

(57) ABSTRACT

A barrier film including: an organic material layer including a single sub-layer or a plurality of sub-layers; and a metal oxide nanosheet layer including a plurality of metal oxide nanosheets; wherein at least one sub-layer of the organic material layer has a positive charge; and an electronic device includes the barrier film.

### CROSS-REFERENCE TO RELATED APPLICATION

This application claims priority to and the benefit of Korean Patent Application No. 10-2016-0026646 filed in the Korean Intellectual Property Office on Mar. 4, 2016, the entire contents of which are incorporated herein by reference.

### BACKGROUND

1. Field

A barrier film and an electronic device are disclosed.

2. Description of the Related Art

An electronic device such as a liquid crystal display (LCD) and an organic light emitting device includes a barrier film to prevent performance degradation caused by permeating aqueous vapor or oxygen and the like. The barrier film may be produced by, for example, coating an inorganic material such as silica (SiOₓ) or alumina (Al₂O₃) onto the electronic device using vacuum deposition. However, vacuum deposition is limited by the available equipment and the high cost. Alternatively, the barrier film may be produced using an organic polymer material, but these films may have undesirable mechanical properties.

Recently, it has been attempted to develop a barrier film having an organic/inorganic hybrid form where organic and inorganic materials are applied together. There nonetheless remains a need in the art for improved organic/inorganic hybrid barrier films, particularly films that have excellent oxygen transmission rate and a reduced number of coatings.

### SUMMARY

An embodiment provides a thin barrier film by reducing the number of coating and simultaneously being capable of ensuring excellent oxygen transmission rate characteristics.

Another embodiment provides an electronic device including the barrier film.

According to an embodiment, a barrier film includes an organic material layer including a single sub-layer or a plurality of sub-layers; and a metal oxide nanosheet layer consisting of, consisting essentially of, or including a plurality of metal oxide nanosheets, wherein at least one sub-layer of the organic material layer has a positive charge.

According to an embodiment, a method of preparing a barrier film includes forming an organic material layer, wherein the organic material layer includes a single sub-layer or a plurality of sub-layers; and forming a metal oxide nanosheet layer, wherein the metal oxide nanosheet layer includes a plurality of metal oxide nanosheets; wherein at least one sub-layer of the organic material layer has a positive charge.

The metal oxide nanosheet may include a metal oxide represented by Chemical Formula 1.

MₓO_{y} Chemical Formula 1

In the above Chemical Formula 1,

M is a transition metal,

O is oxygen, and

x and y denote a stoichiometric content of M and O.

The M may be titanium (Ti), zinc (Zn), ruthenium (Ru), or a combination thereof.

The one metal oxide nanosheet may have a thickness of less than or equal to about 10 nanometers (nm).

In the metal oxide nanosheet layer, the plurality of metal oxide nanosheets may be stacked.

The metal oxide nanosheet layer may have a negative charge, and may be disposed directly on the sub-layer having a positive charge of the organic material layer.

The organic material layer may have a structure wherein the sub-layer having a positive charge and the sub-layer having a negative charge are alternately stacked.

The sub-layer having a positive charge may include poly(allylamine hydrochloride) (PAH), poly(diallyldimethylammonium chloride) (PDDA), polyethylenimine (PEI), poly-L-Lysine hydrochloride, or a combination thereof.

The sub-layer having a negative charge may include poly(anetholesulfonic acid, sodium salt), poly(sodium 4-styrenesulfonate) (PSS), poly(vinyl sulfate, potassium salt), poly(vinylphosphonic acid, sodium salt), poly(acrylic acid, sodium salt) (PAA), or a combination thereof.

The barrier film may further include a substrate having a negative charge, and the sub-layer having a positive charge of the organic material layer may be directly disposed on the substrate.

The barrier film may include a plurality of unit structures including the organic material layer and the metal oxide nanosheet layer.

At least one metal oxide nanosheet of the plurality of nanosheets may have a size of about 1 micrometer (μm) to about 50 μm.

The metal oxide nanosheet layer may have a thickness of less than or equal to about 100 nm.

The barrier film may have a thickness of less than or equal to about 1,000 nm.

According to another embodiment, an electronic device includes the barrier film.

The electronic device may be a flat panel display, a touch panel screen, a solar cell, an e-window, or a transistor.

Additional aspects will be set forth in part in the description which follows and, in part, will be apparent from the description, or may be learned by practice of the presented exemplary embodiments.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view showing a cross-section of a barrier film according to an exemplary embodiment,

FIG. 2 is a schematic cross-sectional view of organic light emitting device according to an exemplary embodiment,

FIG. 3 is a scanning electron microscope (SEM) photograph showing a shape of the composition represented by the formula K_{0.8}Ti_{1.73}Li_{0.27}O₄ synthesized from Example 1,

FIG. 4 is a graph of peak intensity (a.u., arbitrary units) versus diffraction angle (degrees 2 theta) illustrating an X-ray diffraction (XRD) graph of the composition represented by the formula K_{0.8}Ti_{1.73}Li_{0.27}O₄ synthesized from Example 1,

FIG. 5 is a schematic view showing the layered structure of the composition represented by the formula K_{0.8}Ti_{1.73}Li_{0.27}O₄ synthesized from Example 1,

FIGS. 6 to 9 are SEM photographs showing a process of forming a metal oxide nanosheet layer in a process of manufacturing the barrier film according to Example 1, and

FIG. 10 is an SEM photograph showing a cross-sectional view of the barrier film obtained from Example 1.

### DETAILED DESCRIPTION

Exemplary embodiments will hereinafter be described in detail, and may be easily performed by those who have common knowledge in the related art. However, this disclosure may be embodied in many different forms and is not construed as limited to the exemplary embodiments set forth herein.

In this regard, the present embodiments may have different forms and should not be construed as being limited to the descriptions set forth herein. However, this disclosure may be embodied in many different forms and is not construed as limited to the exemplary embodiments set forth herein. Accordingly, the embodiments are merely described below, by referring to the figures, to explain aspects. “or” means “and/or.” As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In addition, unless explicitly described to the contrary, the word “comprise” and variations such as “comprises” or “comprising”, will be understood to imply the inclusion of stated elements but not the exclusion of any other elements.

Further, the singular includes the plural unless mentioned otherwise. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. In the drawings, the thickness of layers, films, panels, regions, etc., are exaggerated for clarity. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

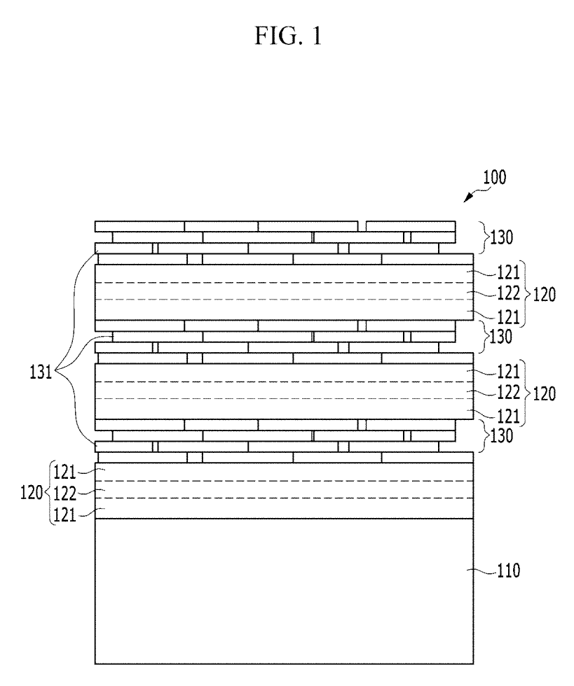

Hereinafter, a barrier film according to an embodiment is described with reference to FIG. 1.

FIG. 1 is a schematic view showing a cross-section of a barrier film according to an embodiment.

Referring to FIG. 1, a barrier film 100 includes a substrate 110, an organic material layer 120, and a metal oxide nanosheet layer 130.

The organic material layer 120 consists of an organic material, and the organic material may include, for example, an organic polymer. The organic material layer 120 may consist of a plurality of sub-layers 121 and 122 or a single layer (i.e., a single sub-layer).

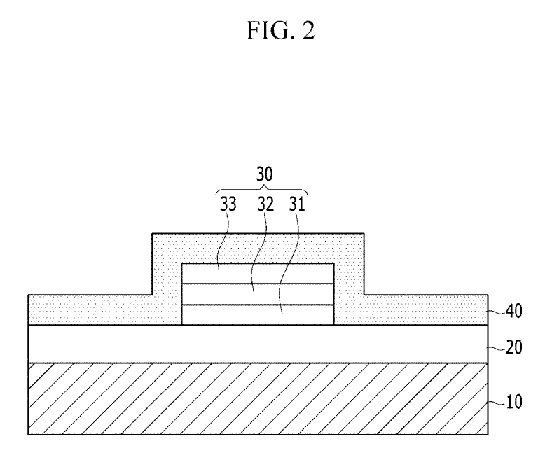

For example, when the organic material layer 120 is formed in a single layer, in other words, when an organic material layer 120 consists of one sub-layer, the layer has a positive charge. For example, when the organic material layer 120 consists of a plurality of sub-layers, at least one sub-layer has a positive charge. For example, the two sub-layers 121 in FIG. 2 each may have a positive charge.

The metal oxide nanosheet layer 130 is a layer comprising a plurality of metal oxide nanosheets 131, wherein the metal oxide nanosheet 131 refers to a sheet-shaped metal oxide material having a nanometer-ordered thickness.

For example, the metal oxide nanosheet layer 130 may have a form in which a plurality of metal oxide nanosheets 131 is arranged in a horizontal direction. For example, the metal oxide nanosheet layer 130 may be a plurality of metal oxide nanosheets 131 that are arranged in a horizontal direction. In an exemplary embodiment, the metal oxide nanosheet layer 130 includes a plurality of metal oxide nanosheets 131 that are arranged in both a horizontal direction and a vertical direction. In this case, the plurality of metal oxide nanosheets 131 may be arranged in a vertical stack that includes about ten metal oxide nanosheets or less.

For example, a metal oxide nanosheet of the plurality of metal oxide nanosheets 131 may have a thickness of less than or equal to about 10 nm, for example, a thickness of about 1 nm to about 10 nm. For example, a metal oxide nanosheet of the plurality of metal oxide nanosheets 131 may have a size of sub-micrometer to several hundred micrometers, for example, a size of about 0.1 micrometers (μm) to 1,000 μm. As used herein, the term ‘size’ refers to the largest dimension of a metal oxide nanosheet. Since the individual metal oxide nanosheets of the plurality of metal oxide nanosheets 131 have a micrometer-ordered size, the number of metal oxide nanosheets of the plurality of metal oxide nanosheets 131 for covering a given area may be reduced, that is, a lower number of non-nanosized material sheets needed to cover the same area. Without being bound by theory, the interface between the individual metal oxide nanosheets in the plurality of metal oxide nanosheets 131 is reduced, which inhibits gas transmission.

For example, the plurality of metal oxide nanosheets 131 may include a metal oxide represented by Chemical Formula 1.

MₓO_{y} Chemical Formula 1

### In Chemical Formula 1,

M is a transition metal,

O is oxygen, and

x and y denote a stoichiometric content of M and O.

For example, the transition metal M may be titanium (Ti), zinc (Zn), ruthenium (Ru), or a combination thereof, but is not limited thereto.

The metal oxide nanosheet layer 130 may be disposed on the organic material layer 120, and the metal oxide nanosheet layer 130 may have a negative charge. For example, the metal oxide nanosheet layer 130 may be disposed directly on the sub-layer 121 having a positive charge of the organic material layer 120. In this case, an electrostatic force is generated between the metal oxide nanosheet layer 130 having a negative charge and the organic material layer 121 having a positive charge, such that the bond between the layers in the barrier layer may be further stabilized.

For example, the organic material layer 120 may have a structure in which the sub-layer 121 having a positive charge and the sub-layer 122 having a negative charge are stacked in an alternating manner. Without being bound by theory, this arrangement results in the generation of an electrostatic force between the sub-layers 121,122 in the organic material layer 120 to further stabilize the bond between the sub-layers in the organic material layer 120.

FIG. 1 shows an organic material layer 120 including three sub-layers including a sub-layer 121 having a positive charge, a sub-layer 122 having a negative charge, and a sub-layer 121 having a positive charge, but is not limited thereto; the organic material layer 120 may be designed, for example, to include five or seven sub-layers, or any suitable number of sub-layers.

The sub-layer 121 having a positive charge of the organic material layer 120 may include an organic material, for example, poly(allylamine hydrochloride) (PAH), poly(diallyldimethylammonium chloride) (PDDA), polyethylenimine (PEI), poly-L-Lysine hydrochloride, or a combination thereof, but is not limited thereto, and any suitable organic material capable of supplying a cation may be used as a material of the sub-layer 121 having a positive charge.

The sub-layer 122 having a negative charge of the organic material layer 120 may include an organic material, for example, poly(anetholesulfonic acid, sodium salt), poly(sodium 4-styrenesulfonate) (PSS), poly(vinyl sulfate, potassium salt), poly(vinylphosphonic acid, sodium salt), poly(acrylic acid, sodium salt) (PAA), or a combination thereof, but is not limited thereto, and any suitable organic material capable of supplying an anion may be used as a material of the sub-layer having a positive charge 122.

The substrate 110 may be formed of a polymer having a high heat resistance, for example, a polyimide, a polyacrylate, a polyethylene terephthalate, a polyethylene naphthalate, a polycarbonate, a polyarylate, a polyetherimide, a polyethersulfone, a tricellulose acetate, a polyvinylidene chloride, a polyvinylidene fluoride, an ethylene-vinyl alcohol copolymer, or a combination thereof.

A substrate 110 may be prepared using a surface treatment method that imparts a charge to the substrate 110. For example, the surface of substrate 110 is treated with a corona discharge plasma to enhance the binding characteristics between the organic material layer 120 and the substrate 110.

The substrate 110 may have, for example, a negative charge. For example, the sub-layer 121 having a positive charge of the organic material layer 120 may be disposed directly on the substrate 110. In this case, the electrostatic force generated between a substrate 110 and the sub-layer 121 having a positive charge may stabilize the bond between the sub-layer 121 and the substrate 110.

In the barrier film 100, an organic material layer 120 and a metal oxide nanosheet layer 130 may form one unit structure, and one or a plurality of the unit structures may be stacked on the substrate 110. FIG. 1 shows three unit structures stacked on the substrate 110, however, any number of unit structures may be stacked on the substrate 110 based on a desired thickness of the barrier film, a desired light transmittance, a desired oxygen transmission rate (OTR), or the like, or a combination of the foregoing considerations.

In an exemplary embodiment, the thickness of the barrier film 100 may be, for example, less than or equal to about 1,000 nm, for example, a thickness of about several nm to about several hundred nm, for example about 4 nm to about 500 nm. For example, the organic material layer 120 may have a thickness of less than or equal to about 100 nm for example, about several nm to several ten nm, or about 4 to about 50 nm. For example, the metal oxide nanosheet layer 130 may have a thickness of less than or equal to about 100 nm, for example, a thickness of about 1 nm to about 50 nm.

The barrier film 100 according to an embodiment may provide a light transmittance of greater than or equal to about 90% and an oxygen transmission rate of less than or equal to about 50 cubic centimeters per inverse square meters per day per atmosphere (cc/m²·day·atm) at a thickness of less than or equal to about 100 nm.

In an exemplary embodiment, the organic material layer 120 and the metal oxide nanosheet layer 130 may be coated using a solution coating process. The organic material layer 120 and the metal oxide nanosheet layer 130 may be coated using a coating process, for example, dip coating, spray coating, slit coating, inkjet coating, and the like, but is not limited thereto.

The barrier film 100 according to an embodiment may exhibit excellent barrier properties, such as a decreased oxygen transmission rate for a lower cost by incorporating alternately stacked organic material layers and metal oxide nanosheet layers including the predetermined metal oxide. The barrier film according to an embodiment may have a coating film thickness that is less than a coating film thickness of a barrier film coated with only organic material; and may not require the use of expensive deposition equipment since it may be applied by a solution process, compared to a barrier film coating with only an inorganic material. Because the barrier film 100 according to an exemplary embodiment uses a metal oxide nanosheet as the inorganic material, a barrier film 100 having excellent barrier characteristics may be obtained while reducing the number of stacked layers, as compared to a barrier film prepared using montmorillonite (MMT), for which a greater number of stacked layers were used to achieve a comparable oxygen transmission rate.

The barrier film may be applied to various electronic devices. The electronic device may be, for example, a flat panel display such as an organic light emitting device, a liquid crystal display (LCD), a touch panel screen, a solar cell, an e-window, or a transistor, but is not limited thereto. In an exemplary embodiment, the barrier film may be employed for a quantum dot display.

Hereinafter, as one example of the electronic device, an organic light emitting device employing the barrier film is described with reference to drawings.

FIG. 2 is a schematic cross-sectional view of an organic light emitting device according to another embodiment.

Referring to FIG. 2, an organic light emitting device according to an embodiment includes a substrate 10, a barrier layer 20, an organic light emitting diode 30, and an encapsulation layer 40.

The substrate 10 may be an inorganic material such as a glass or an organic material such as a polycarbonate, a polymethyl methacrylate, a polyethylene terephthalate, a polyethylene naphthalate, a polyamide, a polyethersulfone, or a combination thereof, a silicon wafer, and the like.

The barrier layer 20 is the same as described above for the barrier film 100, and is disposed on the substrate 10 to prevent moisture and/or gas from permeating into an electronic device.

The organic light emitting diode 30 is disposed on the barrier layer 20, and includes a lower electrode 31, an upper electrode 33, and an emission layer 32 between the lower electrode 31 and the upper electrode 33.

One of the lower electrode 31 and the upper electrode 33 is a cathode and the other is an anode. For example, the lower electrode 31 may be an anode and the upper electrode 33 may be a cathode.

At least one of the lower electrode 31 and the upper electrode 33 is transparent. When the lower electrode 31 is transparent, an organic light emitting device may have a bottom emission in which a light is emitted toward the substrate 10, while when the upper electrode 33 is transparent, the organic light emitting device may have a top emission in which a light is emitted toward the opposite of the substrate 10. In addition, when the lower electrode 31 and upper electrode 33 are both transparent, a light may be emitted toward the substrate 10 and the opposite of the substrate 10 in both ways.

The emission layer 32 may be made of an organic material that inherently emits one color of light among three primary colors such as red, green, blue, and the like, or a mixture of an inorganic material and an organic material, for example, a polyfluorene derivative, a polypara-phenylenevinylene derivative, a polyphenylene derivative, a polyfluorene derivative, a polyvinylcarbazole, a polythiophene derivative, or a compound prepared by doping at least one of these polymer materials with a perylene-based pigment, a coumarin-based pigment, a rothermine-based pigment, rubrene, perylene, 9,10-diphenylanthracene, tetraphenylbutadiene, Nile red, coumarin, quinacridone, and the like. An organic light emitting device displays a desirable image by a combination of primary colors emitted by an emission layer therein.

The emission layer 32 may emit white light by combining basic colors such as tree primary colors of red, green, and blue, and in this case, the color coordination may emit white light by combining the colors of adjacent pixels or by combining colors laminated in a perpendicular direction.

An encapsulation layer 40 covering the organic light emitting diode 30 is disposed on the organic light emitting diode 30 to prevent the permeation of oxygen, moisture, and the like. The material and the forming method of encapsulation layer 40 are not particularly limited, and any suitable material and method may be used.

Hereinafter, the embodiments are illustrated in more detail with reference to examples. However, these embodiments are exemplary, and the present disclosure is not limited thereto.

### EXAMPLES

### Manufacture of Barrier Film

### Example 1

### (1) Formation of Organic Material Layer

The surface of a polyethylene terephthalate (PET) substrate is treated with a corona plasma to provide a substrate surface having a negative charge. A solution including polyethylenimine (PEI) is coated on the PET substrate to provide an organic material layer having a positive charge; and a poly(sodium acrylate) (PAA) solution is coated thereon to provide an organic material having a negative charge; and then a PEI solution, which is an organic material layer having a positive charge, is coated thereon again to provide 3-layered organic material layer. For the PEI solution, 0.1 wt % of PEI having a molecular weight of 25,000 grams per mole (g/mol) is dispersed in deionized (DI) water, and then pH thereof is adjusted to pH 10 using a 1 molar (M) HCl solution. For the PAA solution, 0.2 wt % of PAA having a molecular weight of 100,000 g/mol is dispersed in DI water, and the pH thereof is adjusted to pH 4 using a 1M NaOH solution. Each layer is applied by dipping the substrate into the appropriate solution. The coating is performed over the course of 1 minute for each layer, and each the layer is dried after each coating.

### Synthesis of Metal Oxide Nanosheet

After synthesizing two phases of K_{0.8}Ti_{1.73}Li_{0.27}O₄ and K₂MoO₄ using a flux method, K₂MoO₄, which is a flux soluble in water, is removed to synthesize TiO₂ nanosheets.

First, raw powders of TiO₂, K₂Co₃, Li₂Co₃, and MoO₃ are mixed at a mole ratio of 1.73:1.67:0.135:1.27 and then heated. The heat treatment is performed by maintaining the mixture at a temperature of 1100° C. for 12 hours and then slowly cooling the same to a temperature of 850° C. for 83.3 hours to grow monocrystals. After the heat treatment, the flux is removed to provide a K_{0.8}Ti_{1.73}Li_{0.27}O₄ phase.

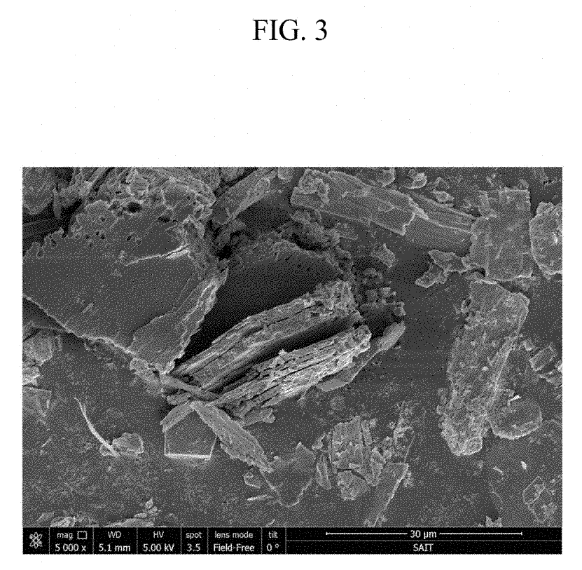

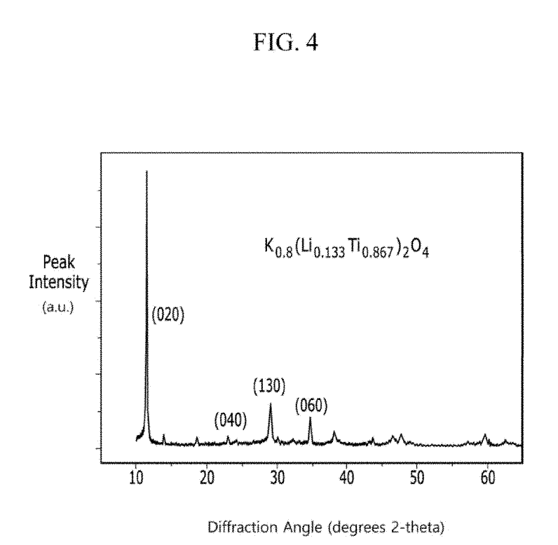

FIG. 3 is a scanning electron microscope (SEM) photograph showing the shape of the synthesized composition represented according to the formula K_{0.8}Ti_{1.73}Li_{0.27}O₄. Referring to FIG. 3, it is understood that K_{0.8}Ti_{1.73}Li_{0.27}O₄ has a layered structure. In addition, in order to confirm the crystal structure of the synthesized K_{0.8}Ti_{1.73}Li_{0.27}O₄, an X-ray diffraction (XRD) analysis is performed. FIG. 4 is an XRD graph showing the peaks obtained by XRD for the synthesized K_{0.8}Ti_{1.73}Li_{0.27}O₄. Referring to FIG. 4, it is confirmed that a monocrystal is formed, wherein the monocrystal has a major peak that corresponds to a 020 face and a minor peak that corresponds to a 130 face.

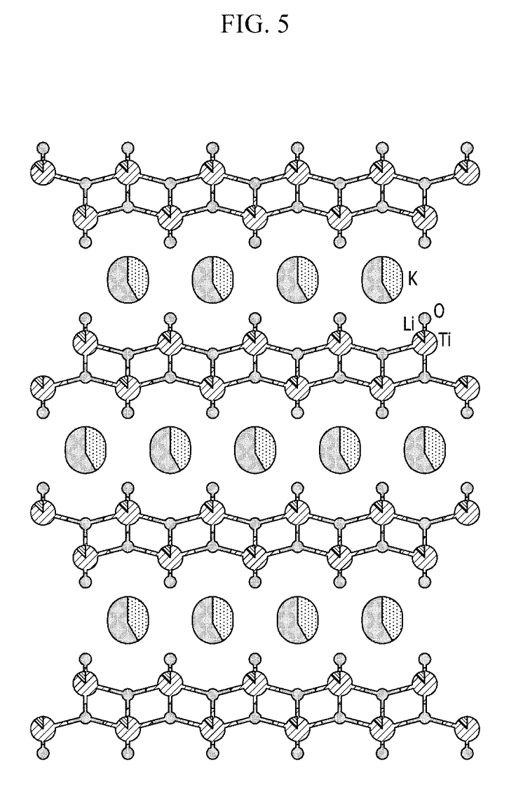

FIG. 5 is a schematic view showing the layered structure of the synthesized K_{0.8}Ti_{1.73}Li_{0.27}O₄. Referring to FIG. 5, in the K_{0.8}Ti_{1.73}Li_{0.27}O₄ layered structure, potassium is interposed between the layers. Thus, potassium is substituted with hydrogen and then substituted with tetrabutylammonium hydroxide (TBAOH) having a larger size to induce the interlayer separation, so that TiO₂ nanosheets are obtained.

The K_{0.8}Ti_{1.73}Li_{0.27}O₄ powder is added to an HCl solution in an amount of 25 g of K_{0.8}Ti_{1.73}Li_{0.27}O₄ powder per 1 liter (L) of the 1M HCl solution and maintained for 3 days at room temperature, wherein the HCl solution is replaced each day. After completing the process, the resulting product is filtered and washed with water to remove HCl, and the powder is obtained and dried. Lastly, 0.8 g of the powder and 0.73 g of tetrabutylammonium hydroxide (TBAOH) are added to 200 milliliters (mL) of DI water and maintained for greater than or equal to 10 days at room temperature, resulting in delamination and the formation of a TiO₂ nanosheet dispersion having a composition of Ti_{0.87}O₂. The thus obtained TiO₂ nanosheet dispersion is further diluted using a dialysis process for removing TBAOH and to provide a final concentration of about 0.2 wt % of TiO₂ in water.

### (3) Forming Metal Oxide Nanosheet Layer

The TiO₂ nanosheet dispersion obtained from hereinabove is coated directly onto the organic material layer obtained from hereinabove using a dip coating method. The coating is adjusted after 10 minutes. Through the process, a barrier film having a layered structure of PET/corona(C) treatment/(PEI/PAA/PEI/TiO₂)₁ is obtained.

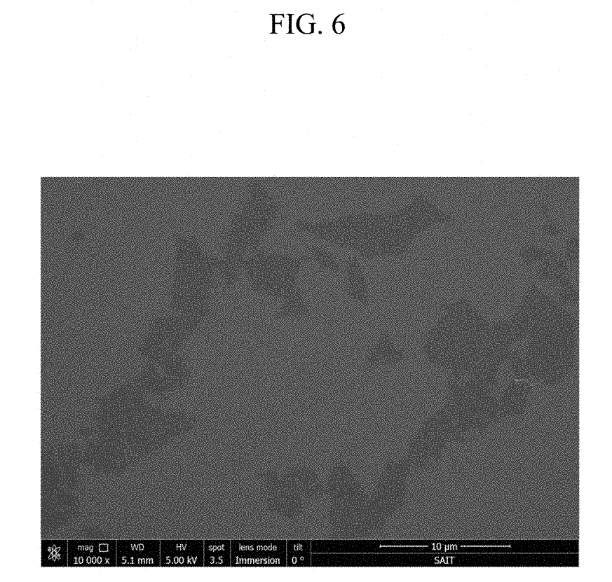

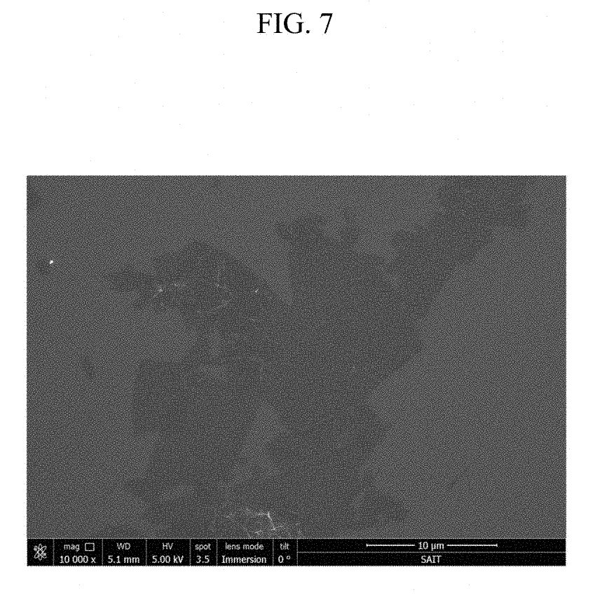

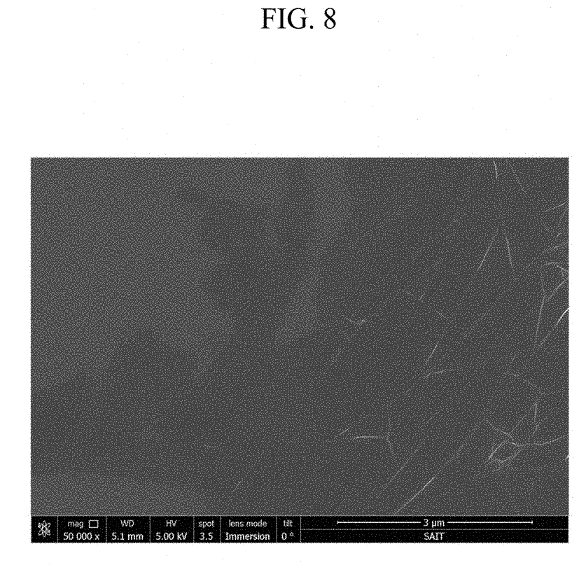

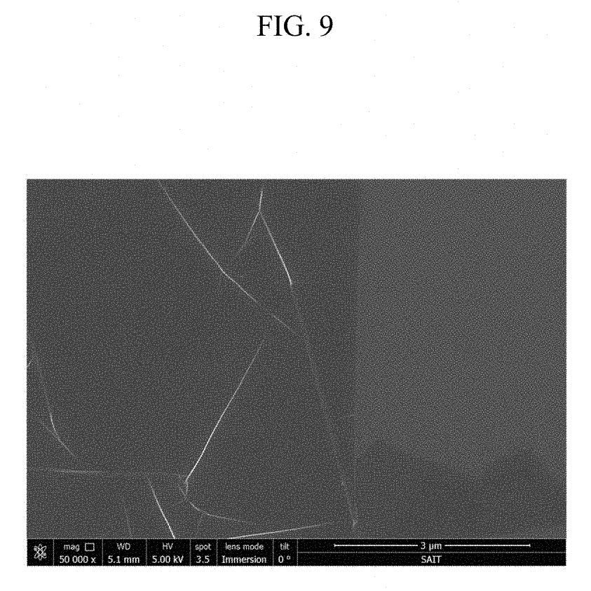

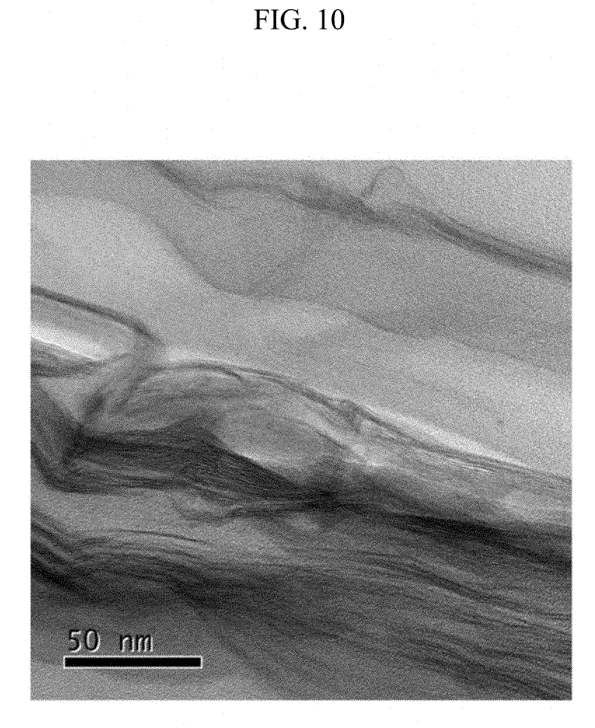

FIGS. 6 to 9 are SEM photographs showing the progression in forming a metal oxide nanosheet layer in a process of producing a barrier film according to Example 1. Referring to FIGS. 6 to 9, it is confirmed that metal oxide nanosheets are coated onto the organic material layer. FIG. 9 is a SEM photograph showing the finally formed metal oxide nanosheet layer. Referring to FIG. 9, it is understood that the size of the metal oxide nanosheets formed on the organic material layer varied from several micrometers to several tens of micrometers. FIG. 10 is an SEM photograph showing a cross-sectional view of the barrier film obtained from Example 1. Referring to FIG. 10, it is confirmed that the barrier film including the layered structure of (PEI/PAA/PEI/TiO2)₁ is formed.

### Example 2

A barrier film having a layered structure of PET/corona(C) treatment/(PEI/PAA/PEI/TiO2)₃ is obtained in accordance with the same procedure as in Example 1, except that the layering steps are repeated 3 times to provide a barrier film having three unit structures.

### Example 3

A barrier film having a layered structure of PET/corona(C) treatment/(PDDA/TiO₂)₁ is obtained in accordance with the same procedure as in Example 1, except that the organic material layer is formed in a monolayer using a poly(diallyldimethylammonium chloride) (PDDA) solution. For the PDDA solution, 2.0 wt % of PDDA having a molecular weight of 100,000 to 200,000 g/mol is dispersed in DI water, and then the pH is adjusted to pH 9 using a 1M HCl solution.

### Example 4

A barrier film having a layered structure of PET/corona(C) treatment/(PDDA/TiO₂)₃ is obtained in accordance with the same procedure as in Example 3, except that the layering steps are repeated 3 times to provide a barrier film having three unit structures.

### Example 5

A barrier film having a layered structure of PET/corona(C) treatment/(PDDA/PAA/PDDA/TiO₂)₁ is obtained in accordance with the same procedure as in Example 1, except that a PDDA solution is used instead of the PEI solution to provide an organic material layer having a positive charge. For the PDDA solution, 2.0 wt % of PDDA having a molecular weight of 100,000 to 200,000 g/mol is dispersed in DI water, and then the pH is adjusted to pH 9 using a 1M HCl solution.

### Example 6

A barrier film having a layered structure of PET/corona(C) treatment/(PDDA/PAA/PDDA/TiO₂)₃ is obtained in accordance with the same procedure as in Example 5, except that the layering steps are repeated 3 times to provide a barrier film having three unit structures.

### Example 7

A barrier film having a layered structure of PET/corona(C) treatment/(PDDA/PSS/PDDA/TiO₂)₁ is obtained in accordance with the same procedure as in Example 1, except that a PDDA solution is used instead of a PEI solution for providing an organic material layer having a positive charge, and a poly(sodium 4-styrenesulfonate) (PSS) solution is used instead of the PAA solution for providing an organic material layer having a negative charge. For the PDDA solution, 2.0 wt % of PDDA having a molecular weight of 100,000 to 200,000 g/mol is dispersed in DI water, and then the pH is adjusted to pH 9 using a 1M HCl solution. For the PSS solution, 0.2 wt % of PSS having a molecular weight of 70,000 g/mol is dispersed in DI water, and then the pH is adjusted to pH 4 using a 1M NaOH solution.

### Example 8

A barrier film having a layered structure of PET/corona(C) treatment/(PDDA/PSS/PDDA/TiO₂)₃ is obtained in accordance with the same procedure as in Example 7, except that the layering steps are repeated 3 times to form a barrier film having three unit structures.

### Example 9

A barrier film having a layered structure of PET/corona(C) treatment/(PDDA/PSS/PDDA/TiO₂)₅ is obtained in accordance with the same procedure as in Example 7, except that layering steps are repeated 5 times to provide a barrier film having five unit structures.

### Example 10

A barrier film having a layered structure of PET/corona(C) treatment/(PEI/PSS/PEI/TiO₂)₁ is obtained in accordance with the same procedure as in Example 1, except that a PSS solution as used instead of a PAA solution for providing an organic material layer having a negative charge. For the PSS solution, 0.2 wt % of PSS having a molecular weight of 70,000 g/mol is dispersed in DI water, and then the pH is adjusted to pH 4 using a 1M NaOH solution.

### Example 11

A barrier film having a layered structure of PET/corona(C) treatment/(PEI/PSS/PEI/TiO₂)₃ is obtained in accordance with the same procedure as in Example 10, except that the layering steps are repeated 3 times to provide a barrier film having three unit structures.

### Example 12

A barrier film having a layered structure of PET/corona(C) treatment/(PEI/PSS/PEI/TiO₂)₅ is obtained in accordance with the same procedure as in Example 10, except that the layering steps are repeated 5 times to provide a barrier film having five unit structures.

### Evaluation 1: Oxygen Transmission Rate (OTR)

The barrier films obtained from Examples 1 to 12 are evaluated to determine the rate of oxygen transmission. The oxygen transmission rate is measured according to ASTM D-3985 using an Oxtran 2/21 ML instrument manufactured by MOCON (Minneapolis, Minn.).

### Evaluation 2: Light Transmittance

The barrier films obtained from Examples 1 to 12 and the bare PET film from Example 1 are evaluated for light transmittance characteristics. The light transmittance is measured using Haze Meter NDH 7000SP manufactured by NIPPON DENSHOKU.

The results of Evaluations 1 and 2 are shown in Table 1:

TABLE 1

| | | Transmittance | OTR |
|---|---|---|---|
| | Structure | (%) | (cc/m² · day · atm) |
| Reference | PET film | 92.7 | — |
| Example 1 | | | |
| Example 1 | PET/C/(PEI/PAA/PEI/TiO₂)₁ | 92.26 | 2.2 |
| Example 2 | PET/C/(PEI/PAA/PEI/TiO₂)₃ | 89.72 | 0.38 |
| Example 3 | PET/C/(PDDA/TiO₂)₁ | 92.53 | 19.0 |
| Example 4 | PET/C/(PDDA/TiO₂)₃ | 91.17 | 6.0 |
| Example 5 | PET/C/(PDDA/PAA/PDDA/TiO₂)₁ | 92.35 | 15.5 |
| Example 6 | PET/C/(PDDA/PAA/PDDA/TiO₂)₃ | 89.83 | 1.8 |
| Example 7 | PET/C/(PDDA/PSS/PDDA/TiO₂)₁ | 92.47 | 20.1 |
| Example 8 | PET/C/(PDDA/PSS/PDDA/TiO₂)₃ | 90.72 | 6.6 |
| Example 9 | PET/C/(PDDA/PSS/PDDA/TiO₂)₅ | 88.21 | 5.0 |
| Example 10 | PET/C/(PEI/PSS/PEI/TiO₂)₁ | 92.77 | 20.1 |
| Example 11 | PET/C/(PEI/PSS/PEI/TiO₂)₃ | 90.78 | 2.4 |
| Example 12 | PET/C/(PEI/PSS/PEI/TiO₂)₅ | 90.65 | 1.9 |

(in Table 1, PET/C indicates that the surface of the bare PET film is treated with a corona plasma)

Referring to Table 1, the barrier films obtained from Examples 1 to 12 have an oxygen transmission rate of less than or equal to about 20.1 cc/m²·day·atm. In addition, the measured oxygen transmission rates varied based on the thickness of each barrier film. Examples having a single unit structure had the highest oxygen transmission rates, while the examples with either three or five unit structures had lower oxygen transmission rates. Thus, the oxygen transmission rate could be tailored based on the desired thickness of the barrier film.

In addition, referring to Table 1, the barrier films obtained from Examples 1 to 12 have a transmittance of about 88% to about 93%, which is nearly equivalent to the transmittance (92.7%) of the PET film from Reference Example 1.

It should be understood that embodiments described herein should be considered in a descriptive sense only and not for purposes of limitation. Descriptions of features or aspects within each embodiment should be considered as available for other similar features or aspects in other embodiments.

While an embodiment has been described with reference to the figures, it will be understood by those of ordinary skill in the art that various changes in form and details may be made therein without departing from the spirit and scope as defined by the following claims.

While this disclosure has been described in connection with what is presently considered to be practical exemplary embodiments, it is to be understood that the disclosure is not limited to the disclosed embodiments, but, on the contrary, is intended to cover various modifications and equivalent arrangements included within the spirit and scope of the appended claims.

What is claimed is:

1. A barrier film comprising:
an organic material layer comprising a single sub-layer or a plurality of sub-layers; and
a metal oxide nanosheet layer comprising a plurality of metal oxide nanosheets,
wherein at least one sub-layer of the organic material layer has a positive charge.

2. The barrier film of claim 1, wherein at least one metal oxide nanosheet of the plurality of metal oxide nanosheets comprises a metal oxide represented by Chemical Formula 1:
MₓO_{y} Chemical Formula 1
wherein, in Chemical Formula 1,
M is a transition metal;
O is oxygen, and
x and y denote a stoichiometric content of M and O.

3. The barrier film of claim 2, wherein the M is titanium, zinc, ruthenium, or a combination thereof.

4. The barrier film of claim 2, wherein the at least one metal oxide nanosheet has a thickness of less than or equal to about 10 nanometers.

5. The barrier film of claim 1, wherein in the metal oxide nanosheet layer, the plurality of metal oxide nanosheets are stacked.

6. The barrier film of claim 1, wherein the metal oxide nanosheet layer has a negative charge, and is disposed directly on the sub-layer having a positive charge of the organic material layer.

7. The barrier film of claim 1, wherein the organic material layer has a structure wherein the sub-layer and the sub-layer having a negative charge are alternately stacked.

8. The barrier film of claim 7, wherein the sub-layer having a positive charge comprises poly(allylamine hydrochloride), poly(diallyldimethylammonium chloride), polyethylenimine, poly-L-lysine hydrochloride, or a combination thereof.

9. The barrier film of claim 7, wherein the sub-layer having a negative charge comprises poly(anetholesulfonic acid, sodium salt), poly(sodium 4-styrenesulfonate), poly(vinyl sulfate, potassium salt), poly(vinylphosphonic acid, sodium salt), poly(acrylic acid, sodium salt), or a combination thereof.

10. The barrier film of claim 1, further comprising a substrate having a negative charge
wherein the sub-layer having a positive charge of the organic material layer is directly disposed on the substrate.

11. The barrier film of claim 1, wherein the barrier film further comprises a plurality of unit structures, wherein a unit structure of the plurality of unit structures comprising the organic material layer and the metal oxide nanosheet layer.

12. The barrier film of claim 2, wherein the at least one metal oxide nanosheet of the plurality of nanosheets has a size of about 1 micrometer to about 50 micrometers.

13. The barrier film of claim 1, wherein the metal oxide nanosheet layer has a thickness of about 100 nanometers.

14. The barrier film of claim 1, wherein the barrier film has a thickness of less than or equal to about 1,000 nanometers.

15. An electronic device comprising the barrier film of claim 1.

16. The electronic device of claim 15, wherein the electronic device is a flat panel display, a touch panel screen, a solar cell, an e-window, or a transistor.

17. A method of preparing a barrier film, the method comprising:
forming an organic material layer, wherein the organic material layer consists of a single sub-layer or a plurality of sub-layers; and
forming a metal oxide nanosheet layer, wherein the metal oxide nanosheet layer consists of a plurality of metal oxide nanosheets,
wherein at least one sub-layer of the organic material layer has a positive charge.

18. The method of claim 17, wherein the plurality of metal oxide nanosheets comprise a metal oxide represented by Chemical Formula 1:
MₓO_{y} Chemical Formula 1
wherein, in Chemical Formula 1,
M is a transition metal;
O is oxygen, and
x and y denote a stoichiometric content of M and O.

19. The method of claim 17, wherein the metal oxide nanosheet layer has a negative charge and is disposed directly on the at least one sub-layer of the organic material layer that has the positive charge.

20. The method of claim 17, wherein the organic material layer further comprises a structure wherein the at least one sub-layer that has the positive charge and a sub-layer that has a negative charge are alternately stacked.
